(19) United States
(12) Patent Application Publication
(10) Pub. No.: US 2005/0083662 A1
(43) Pub. Date: Apr. 21, 2005

(54) Wireless LAN PC card casing

(76) Inventor: Huei-Chen Wong, Taipei County (TW)

Correspondence Address: WONG, Huei-Chen, PO Box 82-144, Taipei, TW

(21) Appl. No.: 10/684,386

(22) Filed: Oct. 15, 2003

(51) Int. Cl. H05K 5/00; H05K 5/04; H05K 5/06

(52) U.S. Cl. 361/752

(57) ABSTRACT

An improved structure of a casing for a wireless LAN PC card (previously known as a PCMCIA) includes a cover and a frame; the cover being related to a plate having at its both sides downwardly folded with multiple clamping and insertion bits; those clamping bits slightly inclined inwardly facing the center of the cover; multiple locking grooves and insertion holes to match those clamping bits and insertion bits being provided on the frame; upon pressing the cover onto the frame, those clamping bits and insertion bits being locked to their respective clamping grooves and insertion holes to firmly incorporated the cover to the frame.

### BACKGROUND OF THE INVENTION

(a) Technical Field of the Invention

The present invention is related to a wireless LAN PC card casing, and more particularly, to one that is comprised of two elementary members of a cover and a frame with the cover lid provided with multiple insertion and clamping bits to allow its fast engagement to the frame by pressing it onto the frame for those bits to lock up their corresponding insertion holes and locking grooves provided on the frame.

(b) Description of the Prior Art

Whereas a casing of a wireless LAN PC card is approximately in the same size as that of a visiting card, the casing contains electronic parts including circuit board, terminals and conductors. Therefore, it is important that the structure of the casing must be sturdy.

The prior art of a wireless LAN PC card casing usually has a frame made of insulation plastic material, and is sandwiched between a cover and a base. The assembly of the casing may be done in any of the following methods:
1. By Laser Welding: with the cover and the base respectively covering up the upper and the lower sides of the frame, a laser welding machine is used to weld the edges where both of the cover and the case meet both sides of the frame to complete the fusion; however, this method is found with the following flaws that the welding machine is expensive to relatively increase the production cost, and that the operation for being comparatively sophisticate that requires specially trained technician to do the welding job frustrates the output.
2. By Adhesion: adhesive is used to bind both of the cover and the base to the frame; however, the flaws about this approach include that the adhesive may be unevenly coated resulting in overflowing of the adhesive, and the adhesive may be deteriorated under higher temperature or relative humidity.
3. As illustrated in FIG. 7, a casing of the prior art is comprised of a cover (40), a base (60) and a frame (50). Wherein, the cover (40) is fully symmetrical to the base (60); and multiple locking bits (41) (61) are respectively extended at where appropriately on both edges of the cover (40) and the base (60). Upon pressing the cover (50) upon the base (60), those locking bits (41) (61) must be provided in an extremely precise shape so to assure that the frame (50) is firmly secured between the cover (40) and the base (60). Any damage or twisting of any of those bits would prevent a perfect engagement between the cover (40) and the base (60). Any poor abutting between those locking bits (41) (61) and the edge of the frame (50) would fail the reliable locking.
4. A further flaw about the method described in the preceding paragraph 3 is that precision dies are required for processing those locking bits (41) (61) respectively provided on both sides of the cover (40) and the base (60) to call for higher production cost.

### SUMMARY OF THE INVENTION

The primary purpose of the present invention is to provide an improved structure of a casing for wireless LAN PC card that allows easy operation and application. To achieve the purpose, the casing is essentially comprised of a cover and a frame. Multiple insertion bits and clamping bits are provided to the cover, and multiple insertion holes and clamping grooves are provided on the frame to respectively match those insertion bits and clamping bits so to respectively lock up those insertion bits and clamping bits of the cover to their corresponding insertion holes and clamping grooves of the frame to firmly secure the cover to the frame.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a view showing the appearance of an assembly of a preferred embodiment of the present invention.

FIG. 2 is an exploded view of the preferred embodiment of the present invention.

FIG. 3 is a sectional view showing the structure of a clamping bit of the present invention taken from location A-A in FIG. 2.

FIG. 4 is a sectional view showing a structure of the preferred embodiment located at where insertion bits are locked to their corresponding insertion holes as taken from location B-B in FIG. 2.

FIG. 5 is a side view of the preferred embodiment of the present invention.

FIG. 6 is a magnified view of a local part of the preferred embodiment of the present invention.

FIG. 7 is an exploded view of the prior art of the present invention.

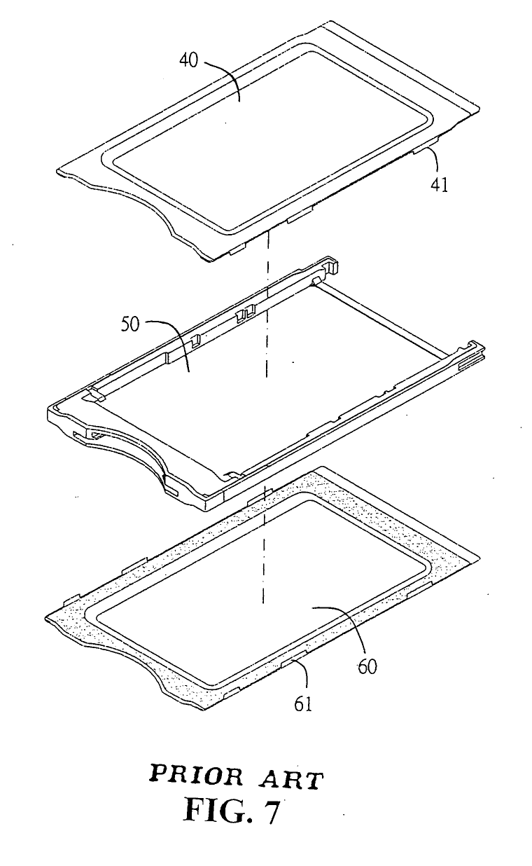

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

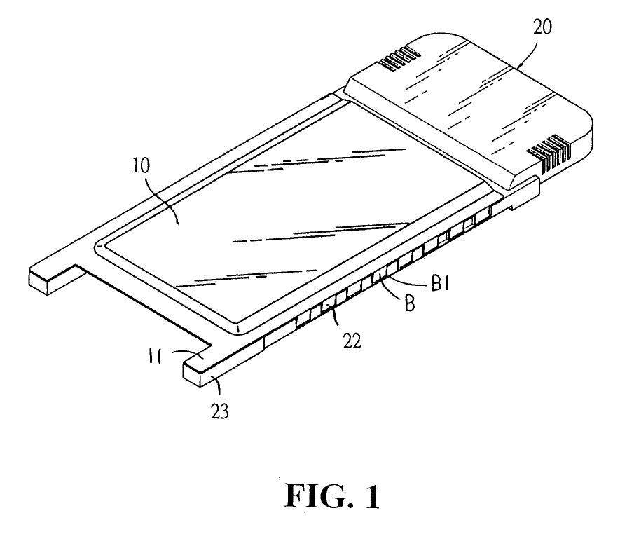

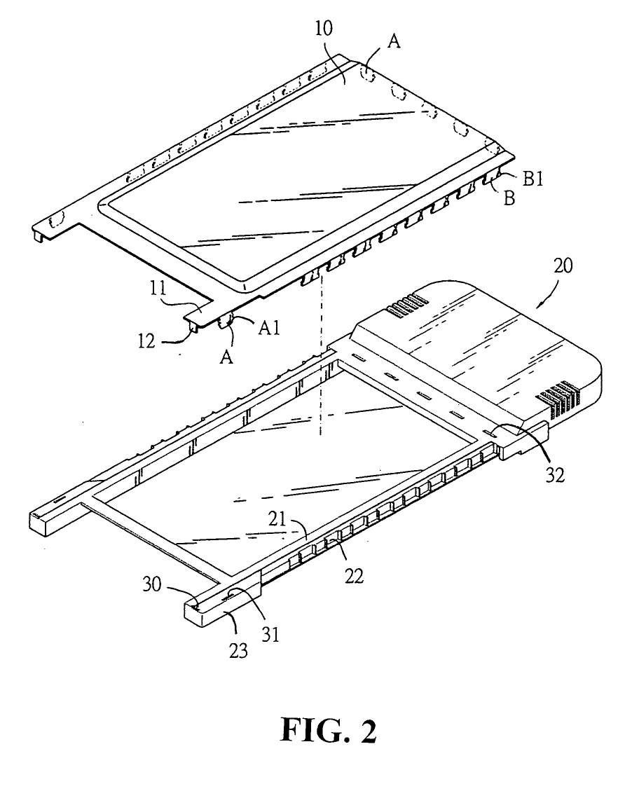

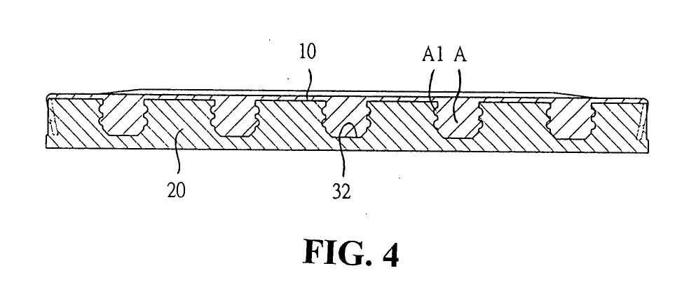

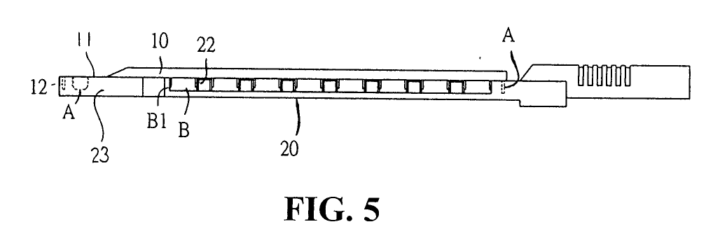

Referring to FIGS. 1 and 2, a preferred embodiment of the present invention is essentially comprised of a cover (10) locked to a frame (20). Wherein, the cover (10) in an approximately plate structure, metallic one preferred, has its both longer sides each provided multiple clamping bits (B) with a given distance from one another. Also referring to FIGS. 1, 2, and 5, those clamping bits (B) extend downward and slightly incline towards the center of the cover (10) and it is preferred that at the lower edge of each clamping bit (B), two ears (B1) are respectively protruding from both ends in an inverse T shape so to give a wider lower part for yielding better holding strength, and preventing deformation due to twisting. Now referring to FIGS. 2 and 4, multiple insertion bits (A) are provided on the rear end of the cover (20) and each insertion bit (A) is respectively provided at its both sides a corrugated hooker (A1). Two tabs (11) respectively extend from both sides on the front end of the cover (10), and at the tip of the tab (11) downwardly folded a front hooker (12). Furthermore, at the front end of the cover (10), e.g., both sides of the tab (11) are respectively provided with the insertion bit (A) having at its both lower ends each provided with a corrugated hooker (A1).

As illustrated in FIG. 2, those clamping bits (B) and those insertion bits (A) are at best arranged in symmetry on both sides of the cover (10).

As illustrated in FIGS. 1 and 2, the frame (20) is essentially provided in a form of a bracket (21). A head (23) is each protruding from both sides of the front end of the frame (20) at where in relation to their matching tabs (11) of the cover (10). Multiple locking grooves (22) are provided to both sides of the frame (20) at where directly in relation to their matching clamping clips (B) of the cover (10); while multiple insertion holes (30) (31)(32) are respectively provided on the front and the rear ends of the bracket (21) at where directly in relation to those insertion bits (A) of the cover (10).

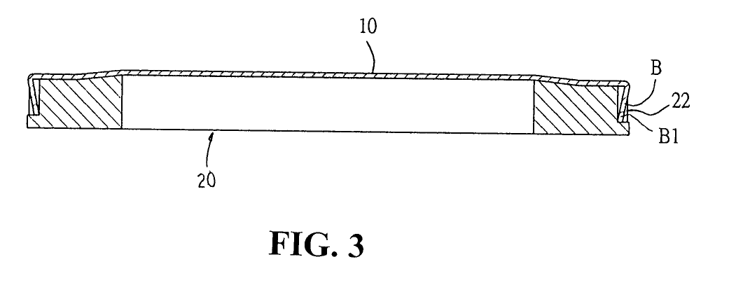

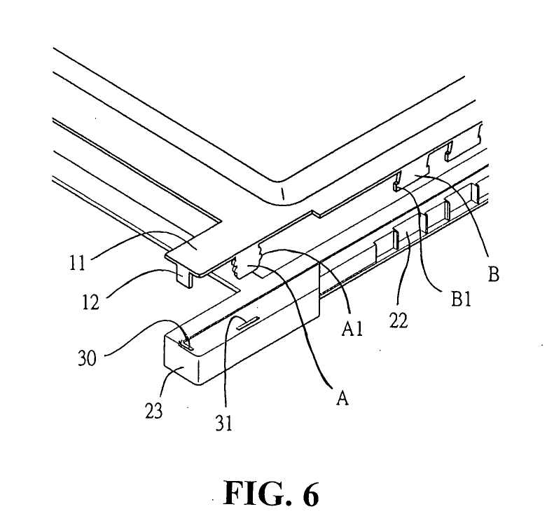

Upon pressing the cover (10) onto the frame (20) as illustrated in FIG. 3, those inwardly inclined clamping bits (B) are locked each into their matching locking grooves (22) of the frame (20); and those insertion bits (A) at the rear end of the cover (10) are each inserted into their matching insertion holes (32) provided at the rear end of the frame (20) as illustrated in FIG. 4. Each insertion bit (A) having its sharp and corrugated insertion hookers (A1) to cut into the sidewall of the insertion hole (32). As illustrated in FIG. 6, the cover (10) has respectively the front hooker (12) at the tip of the protruded tab (11) of the cover (10), and another insertion bit (A) provided on the outer side of the protruded tab (11) to insert into their matching insertion holes (30) (31) provided on the head (23) of the frame (20) to firmly secure the cover (10) to the frame (20).

The present invention provides the following advantages:
1. Since those insertion bits provided on both longer sides of the cover are used to insert into their respective holes provided on the frame, each insertion bit is thick enough to be secured in the insertion hole to yield a strong structure without the necessity to get too precise for cost reduction and providing excellent locking force.
2. The sharp and corrugated hooker each provided on both sides of each insertion bit is capable of cut deeply into the sidewall of the insertion hole to provide excellent holding strength to prevent falling off
3. The expensive laser-welding machine is not required and there is the absence of the problem of escaping adhesive. The present invention gives good heat withstanding performance and dies development costs are under control as it is not necessary for the dies to get too precise permitting further cost saving.
4. As those clamping bits are made slightly curved towards the center of the cover, it is easy for them to firmly lock the frame to support those insertion bits to achieve a more evenly distributed clamping result.
5. As at both sides at the terminal of each clamping bit is each provided with an ear in the inverse T shape, the wider lower part of the clamping bit is given with greater holding strength and less vulnerable to deformation by twisting.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

1. A wireless LAN PC card casing comprised of a cover and a frame, and the cover being secured to the frame is characterized by that:
(a) the cover approximately in a plate structure, having on its peripheral provided multiple clamping bits and insertion bits downwardly folded and substantially in symmetric arrangement, and those clamping bits being curved inwardly toward the center of the cover;
(b) the frame being provided multiple locking grooves at where directly in relation to those clamping bits; and multiple insertion holes at where directly in relation to those insertion bits; the cover being pressed onto the frame; those clamping bits being locked into their respectively locking grooves; and those insertion bits being inserted into their respective insertion holes.

2. A wireless LAN PC card casing as claimed in claim 1, wherein, those multiple insertion bits are arranged at the rear end of the cover.

3. A wireless LAN PC card casing as claimed in claim 1, wherein, at least one insertion bit is each provided on both sides of the front end of the cover.

4. A wireless LAN PC card casing as claimed in claim 1, wherein, those clamping bits are arranged in symmetry on both longer sides of the cover.

5. A wireless LAN PC card casing as claimed in claim 1, wherein, a front hooker extends downwardly from the front end of the cover.

6. A wireless LAN PC card casing as claimed in claim 1, wherein, two protruded tabs respectively extend from both sides of the front end of the cover.

7. A wireless LAN PC card casing as claimed in claim 6 wherein, a front hooker is provided to the protruded tab.

8. A wireless LAN PC card casing as claimed in claim 1, wherein, two ears are respectively provided on both sides at the terminal of the clamping bit in an inverse T shape.

9. A wireless LAN PC card casing as claimed in claim 1, wherein, two corrugated hookers are respectively provided on both sides of each insertion bit.
